(19) United States
(12) Patent Application Publication
(10) Pub. No.: US 2006/0221751 A1
(43) Pub. Date: Oct. 5, 2006

(54) Memory power supply backup system

(76) Inventors: Chuang-hua Chiao, Taipei (TW); Mohammad Farooq Rydhan, San Jose, CA (US)

Correspondence Address: RABIN & BERDO, P.C., Suite 500, 1101 14 Street, N.W., Washington, DC, 20005, US

(21) Appl. No.: 11/092,687

(22) Filed: Mar. 30, 2005

(51) Int. Cl. G11C 5/14

(52) U.S. Cl. 365/229

(57) ABSTRACT

A memory power supply backup system aims to activate and switch a power supply backup system, to provide electric power to a memory, temporarily storing data when the power supply is interrupted abnormally to avoid losing data in the memory. When the power supply is back to normal, the computer system restores to the condition prior to the power supply interruption according to the data temporarily stored in the memory, to continue the unfinished process, thereby to enhance the reliability and stability of the computer system.

### FIELD OF THE INVENTION

The present invention relates to a power supply backup system and particularly to a memory power supply backup system for use in an Advanced Configuration & Power Interface (ACPI) power supply-mode.

### BACKGROUND OF THE INVENTION

With the arrival of the information processing age, computer systems have been widely used in all kinds of businesses. In general, for institutions where communication quality is vital, such as telecommunication companies, data centers, banks, government organizations and military organizations, high-end servers and blade servers are commonly used to store important information in the computer systems. Operation quality of the computer system is very important. For instance, when the bank is processing payment transactions or data transmission, if the power supply disrupts, the transaction data are lost instantly, and unpredictable damage could occur. If the data temporarily stored in the computer system are backed up during the power supply interruption, the transaction data can be saved, and operation quality of the computer system improves. Most of the transaction data are stored temporarily in the memory.

To safeguard the aforesaid circumstance, the commonly approach is adopting an Uninterrupted Power Supply (UPS) system. When the power supply interruption occurs, the data of unfinished process are saved and a backup power supply is provided to enable the computer system to continue the unfinished process and produce backup data. However, setting up and maintaining the UPS system is costly . . .

To remedy the aforesaid situation, some other schemes have been developed. For instance, R.O.C. patent publication No. 525330 discloses a backup power supply system, which automatically wakes up electric equipment when the power supply recovers. It includes the following steps: the electric equipment automatically entering a power saving mode when power supply interruption occurs; detecting ending of the power supply interruption and automatically waking up the electric equipment from the power saving mode to a normal operation mode, thereby avoiding mistaken shutdown of the equipment due to power supply problems, and preventing unnecessary operation troubles. However, the aforesaid patent does not provide a power supply backup system for the memory power of the computer system.

Hence how to provide a low cost method to save the interim data in the memory and prevent damage when the power supply is interrupted, and restore the computer system process to the condition prior to the interruption when the power supply is back to normal, to enhance the reliability and stability of the computer system, is one of the issues yet to be resolved in the industry.

### SUMMARY OF THE INVENTION

In view of the aforesaid disadvantages and problems not yet resolved in the conventional techniques, the primary object of the present invention is to provide a memory power supply backup system, to provide power supply required to save the data in the memory when the power supply is interrupted. Further, to restore the computer system process to the condition prior to the interruption when the power supply is back to normal, thereby to enhancing the reliability and stability of the computer system.

In order to achieve the foregoing object, the memory power supply backup system according to the invention provides a backup power supply to the memory when the power supply is interrupted to temporarily store data in the memory. It includes a power supply detection unit, a power supply backup control unit, a power supply backup unit and a power supply switch unit.

The power supply detection unit aims to detect power supply conditions, and generates a power supply interruption signal when an abnormal condition of the power supply occurs.

The power supply backup control unit aims to generate a backup power supply control signal according to the power supply condition, activate a backup power supply and prepare to deliver electric power.

The power supply switch unit switches the power supply delivery route according to the control signal.

The power supply backup unit provides the backup power supply to temporarily store data in the memory.

The computer system further enters the ACPI S3 mode. In this mode, the computer system merely saves the data in the memory. Hence only the memory needs power supply. The backup power supply can deliver electric power for a longer period of time. When the power supply is back to normal, it also can charge the power supply backup unit to ensure that the power supply backup unit has power delivery capability constantly.

In another aspect, the power supply backup system for the computer system according to the invention includes a memory, a central processing unit, a chip set, a power delivery unit, a power supply detection unit, a power supply backup control unit, and a power supply backup unit.

The memory to temporarily store data to be processed in the computer system.

The central processing unit which is the nuclear module of the computer system to process the data temporarily stored in the memory.

The chip set to control signal transmission of the computer system that includes a south bridge chip set and a north bridge ship set.

The power delivery unit to receive power supply and provide power supply required in the computer system.

The power supply detection unit to detect power supply conditions.

The power supply backup control unit to generate a backup power supply control signal according to the power supply conditions.

The power supply switch unit to switch a power supply delivery route according to the control signal.

The power supply backup unit to provide a backup power supply to temporarily store the data in the memory to be processed by the computer system.

In addition, the invention further provides a memory power supply backup method which includes the following steps:

First, detect the power supply condition and determine whether the present power supply is interrupted. If the power supply is interrupted, the power supply detection unit generates a power supply interruption signal to the power supply backup control unit and prepares to execute a backup power supply delivery process.

Next, the computer system enters ACPI S3 mode and activates the power supply backup unit to supply electric power. After the computer system has entered the S3 mode, switch the power supply delivery route through the power supply backup unit, to deliver electric power to the memory, to store data temporarily.

Detect whether the power supply is back to normal. If the power supply is back to the normal condition, switch the power supply delivery route through the normal power supply to deliver electric power, shut down the power supply backup unit and charge the power supply backup unit, so that the power supply backup unit has the capability to deliver electric power constantly.

By means of the memory power supply backup system set forth above, when power supply of the power supply system is interrupted, the power supply backup system is activated and switched to provide electric power to the memory, to store data temporarily and save the data for the process not yet finished. When the power supply is back to normal, the computer system restores to the condition prior to the power interruption through the data saved in the memory, to continue the unfinished process. Hence the reliability and stability of the computer system are enhanced.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a system block diagram of the invention;

FIG. 2 is a process flow chart of the invention;

FIG. 3 is a circuit diagram of the power supply backup control unit of the invention; and

FIG. 4 is a circuit diagram of the power supply switch unit of the invention.

### DESCRIPTION OF THE PREFERRED EMBODIMENTS

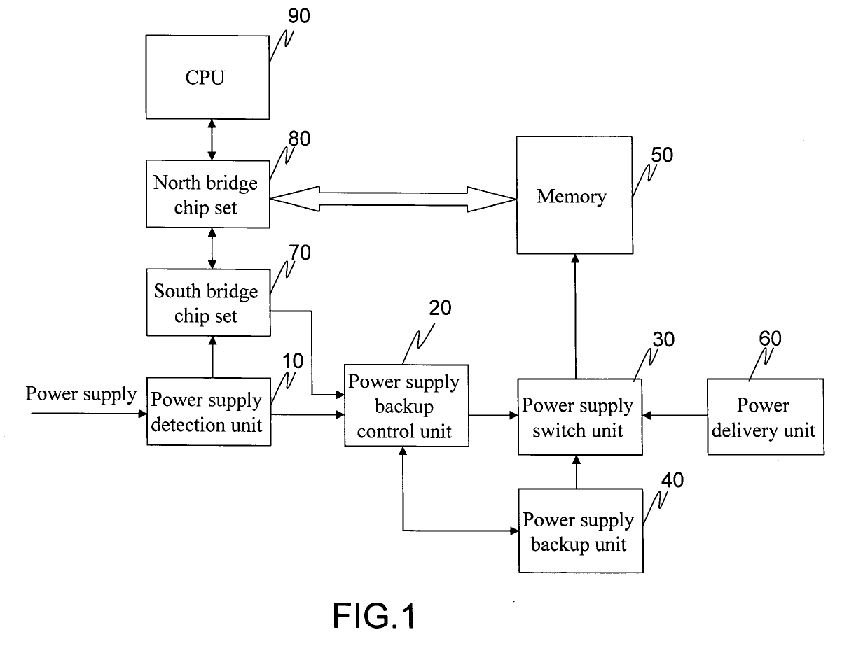

Refer to FIG. 1 for the system block diagram of the invention. It includes a power supply detection unit 10, a power supply backup control unit 20, a power supply switch unit 30 and a power supply backup unit 40.

The power supply detection unit 10 aims to detect power supply conditions, and generates a power supply interruption signal (such as a non-maskable interrupt (NMI) instruction) when an abnormal interruption of the power supply occurs (such as a blackout or abnormal machine shutdown, or the like). At that moment, the computer system must interrupt the operating instructions under processing and execute the NMI instruction, which has a higher processing priority in a central processing unit 90, and all other instructions are suspended.

The power supply backup control unit 20 is connected to the power supply detection unit 10, and generates a backup power supply control signal according to the power supply interruption signal, to activate the power supply backup unit 40. When the power supply is back to normal condition, it controls a charge circuit (not shown in the drawings) to charge the power supply backup unit 40.

The power supply switch unit 30 is connected to the power supply backup control unit 20, to switch a power supply delivery circuit to a power supply backup delivery circuit according to the control signal generated by the power supply backup control unit 20, to provide electric power required by the memory 50, to temporarily store data.

The power supply backup unit 40 is connected to the power supply backup control unit 20 and the power supply switch unit 30. It is activated by the control signal of the power supply backup control unit 20 to provide electric power required by the memory 50 to temporarily store the data through the power supply switch unit 30. The power supply backup unit 40 is a battery, such as a DC battery of 2.5 volts.

In the normal power supply condition, the power supply backup control unit 20 charges the power supply backup unit 40 through the normal power supply to ensure that the power supply backup unit 40 has power supply capability constantly.

The memory 50 is connected to the power supply switch unit 30 to temporarily store the data to be processed in the computer system. The memory 50 can be classified in ‘registered’ and ‘non-registered’. Based on the access method, the memory 50 also can be classified in read only memory (ROM) and random access memory (RAM).

There is a power delivery unit 60 connecting to the power supply switch unit 30. In normal power supply condition, it provides the electric power (such as DC power of 1.8-3.3 volts) required by the memory 50, to temporarily store the data and other modules of the computer system (such as a south bridge chip set 70, a north bridge chip set 80, central processing unit 90, and the like) for operation.

The south bridge chip set 70 is connected to the power supply detection unit 10 and the power supply backup control unit 20 to control signal transmission of the peripheral interfaces of the computer system, including Industry Standard Architecture (ISA), Integrated device Electronics (IDE), a Universal Serial Bus (USB), a Peripheral Controller Interface (PCI), a Low Pin Count Interface (LPC), a System Management Bus (SM Bus), keyboard and mouse.

The south bridge chip set 70 further receives the power supply interruption signal generated by the power supply detection unit 10, to produce a trigger signal of the power supply management mode to enable the computer to enter ACPI S3 mode.

The north bridge chip set 80 is connected to the south bridge chip set 70, to control signal transmission of the main modules of the computer system, including CPU, memory, PCI and Accelerated Graphic Port (AGP).

The CPU 90 is connected to the north bridge chip set 80 and is the nuclear module of the computer system to handle signal processes of various modules.

The power supply backup system of the invention aims to be operated in the ACPI mode to supply electric power to the memory. The ACPI operation mode, especially the sleeping condition, is discussed below for further understanding.

The sleeping condition can be divided into six levels, from S0 to S5 by sequence. The S0 mode is the normal operation mode, namely not sleeping. All the devices in the system function normally.

In the S1 mode, the CPU 90 stops processing. If a wake-up operation is executed, the computer system resumes operation, and data in the system are not lost. The system is restored to the condition prior to the sleeping.

The S2 mode is similar to the S1 mode, but the CPU is shut down. Hence data in the cache memory (not shown in the drawings) are lost. If the wake-up operation is executed, the operation system has to recover the data in the CPU 90 and the cache memory.

In the S3 mode, the computer system saves only the data in the memory 50, but the data in other devices such as CPU 90, cache memory, chip sets (such as a south bridge chip set 70 and north bridge chip set 80) and peripherals are lost. If the wake-up operation is executed, the data in the memory is retrieved directly to continue the process without waiting for the operation system or redo execution of the application programs. Hence restoring of the computer system is faster. But the memory 50 has to receive power supply.

In the S4 mode, the magnetic disk is sleeping. This mode consumes the least electric power. But the process restoring time of the computer system is longer. All devices in the computer system are closed. Hence no electric power is needed. The S5 mode is similar to the S4 mode, but the operation system does not maintain and save any data.

Hence when the computer system enters the S3 mode, only the memory 50 needs power supply. When the power supply is back to normal, the system can be restored quickly and computer-processing efficiency improves.

Therefore, the data in the memory 50 can be saved temporarily. Once the power supply is back to normal, the computer system can retrieve the data that have been stored temporarily. The computer system also inspects error messages of the Error Correction Code (ECC) of the data that have been stored temporarily. If an error message is found, the corresponding data in the memory is deleted to prevent erroneous operation of the peripherals.

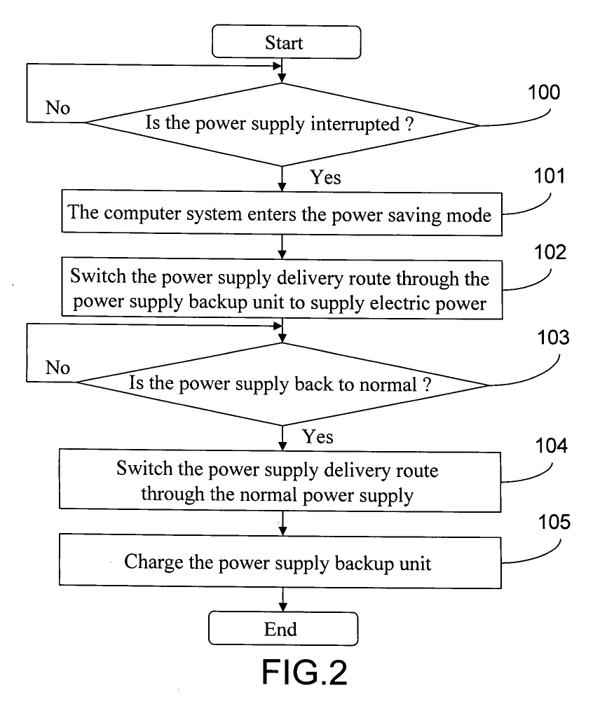

Refer to FIG. 2 for the process flow of the invention. First, detect the power supply condition (step 100) and determine whether the present power supply is interrupted. If the power supply is interrupted, the power supply detection unit 10 generates a power supply interruption signal to the power supply backup control unit 20 and prepares to execute the backup power supply delivery process.

Next, the computer system enters the ACPI S3 mode (step 101), and activates the power supply backup delivery unit 40 to supply electric power. After the computer system has entered the S3 mode, switch the power supply delivery route to the power supply backup unit 40, to deliver electric power (step 102) to the memory 50, to store data temporarily.

Detect whether the power supply is back to normal (step 103). If the power supply is back to normal condition, switch the power supply delivery route to the normal power supply (step 104) to deliver electric power from the power delivery unit 60 to the memory 50, shut down the power supply backup unit 40 and charge the power supply backup unit 40 (step 105), to ensure that the power supply backup unit 40 has the capability to deliver electric power constantly.

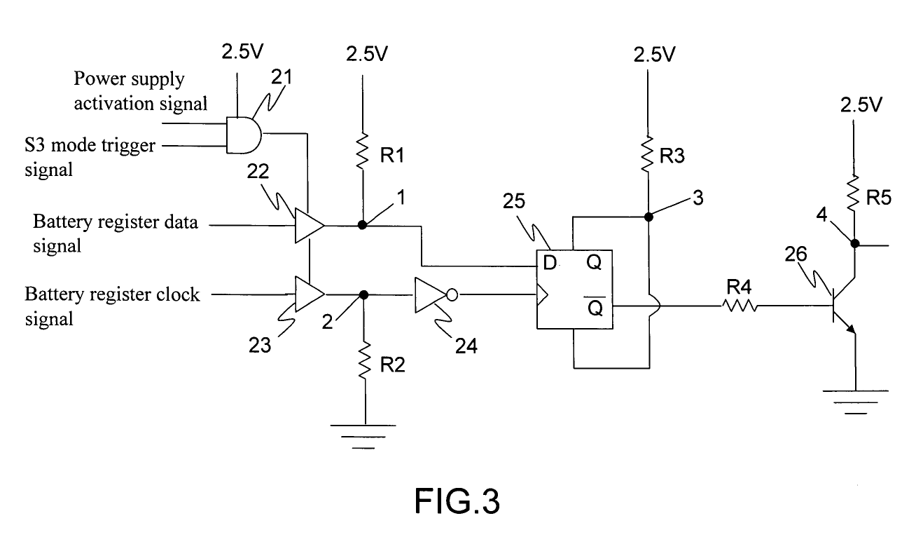

Refer to FIG. 3 for the circuit diagram of the power supply backup control unit of the invention. It includes an AND gate switch 21, a first buffer 22, a second buffer 23, an inverse gate switch 24, a D-inverter 25, a first transistor switch 26 and a first resistor R1 through a fifth resistor R5.

First, the AND gate switch 21 captures a POWER_ON signal and a SLP3_DLY# signal of the S3 mode, the output end of the AND gate switch 21 is connected to the control end of the first buffer 22 and the control end of the second buffer 23.

Next, the input end of the first buffer 22 captures a data signal (BAT_REG_DATA) of the battery register, and the output end of the first buffer 22 is connected to node 1. The first resistor R1 has one end connecting to the node 1 and other end connecting to a voltage source of 2.5 volts.

The input end of the second buffer 23 captures a clock signal (BAT_REG_CLK) of the battery register, and the output end of the first buffer 23 is connected to node 2. The second resistor R2 has one end connected to the node 2 and the other end grounded.

The inverse gate switch 24 has the input end connecting to the node 2 and output end connecting to the clock input end of the D-inverter 25. Next, the D-inverter 25 has the data input end connecting to the node 1.

The third resistor R3 has one end connecting to node 3 and other end connecting to the voltage source of 2.5 volts. The D-inverter 25 has a Preset end and a Clear signal input end connected respectively to the node 3.

The D-inverter 25 has a second output end connecting to the base of the first transistor switch 26 through the fourth resistor R4, the first transistor switch 26 has the emitter grounded and the collector connecting to node 4. The fifth resistor R5 has one end connected to the node 4 and the other end connected to the voltage source of 2.5 volts. The node 4 outputs a backup power supply activation signal (BAT_ON).

In addition, the AND gate switch 21 outputs a switch signal based on the processing result, to drive the power supply switch unit 30 to operate.

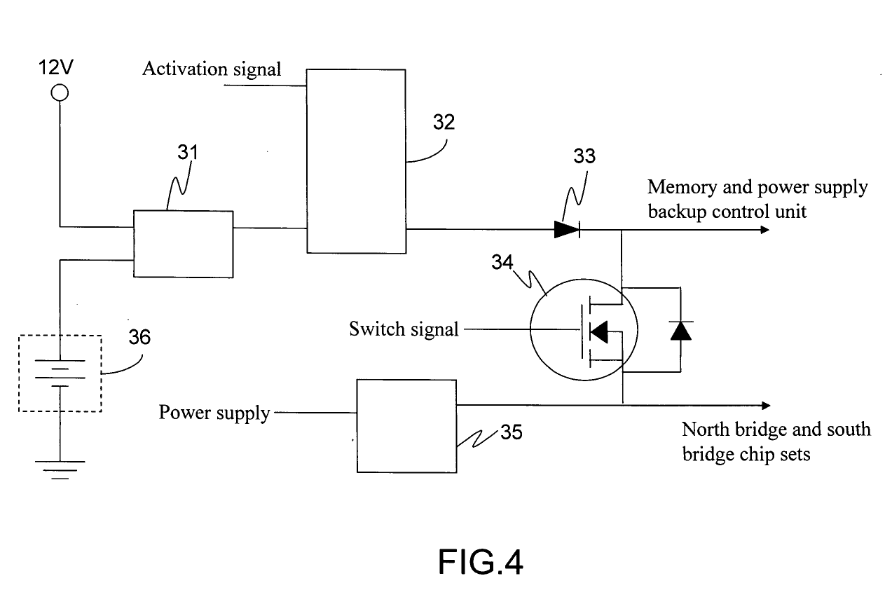

Refer to FIG. 4 for the circuit diagram of the power supply switch unit of the invention. It includes a battery monitor and charger 31, a backup power supply stabilizer 32, a diode switch 33, a second transistor switch 34, a normal power supply stabilizer 35 and a battery 36.

The battery monitor and charger 31 aims to monitor the condition of the battery 36 (such as electricity and temperature) and charge operation on the battery 36. The battery monitor and charger 31 are triggered by the control signal of the power supply backup control unit 20, to activate the charge operation of the battery 36.

The backup power supply stabilizer 32 aims to provide the operation power supply, required for the computer system (such as the DC voltage source of 2.5 volts). The devices in the computer system, using this power supply, include the power supply backup control unit 20 and the memory unit 50.

The diode switch 33 aims to protect the backup power supply stabilizer 32. The second transistor switch 34 is driven ON or OFF by the switch signal to switch the power supply delivery route.

The normal power supply stabilizer 35 aims to provide operation power supply required for the computer system (such as the DC voltage source of 2.5 volts). The devices in the computer system, using this power supply, include the power supply backup control unit 20, memory unit 50, south bridge chip set 70, north bridge chip set 80, and other logic circuits.

By means of the memory power supply backup system set forth above, when the power supply is interrupted abnormally, the computer system enters the ACPI power saving mode, and through activation and switching of the power supply backup system, electric power required for the memory to temporarily store data is provided. When the power supply is back to normal, the computer system continues the unfinished process through the data, temporarily stored in the memory. Therefore the reliability and stability of the computer system are enhanced.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments, which do not depart from the spirit and scope of the invention.

What is claimed is:

1. A memory power supply backup system to provide a backup power supply to a memory when power supply is interrupted to temporarily store data in the memory, comprising:
a power supply detection unit to detect conditions of the power supply;
a power supply backup control unit to generate a control signal of the backup power supply according to the conditions of the power supply;
a power supply switch unit to switch a power delivery route of the power supply according to the control signal; and
a power supply backup unit to provide the backup power supply to allow the memory to temporarily store the data.

2. The memory power supply backup system of claim 1, wherein the power supply detection unit generates a power supply interruption signal when the power supply is interrupted.

3. The memory power supply backup system of claim 2, wherein the power supply interruption signal is a non-maskable interrupt instruction.

4. The memory power supply backup system of claim 1, wherein the power supply switch unit switches to the power supply backup unit to deliver electric power when the power supply is interrupted.

5. The memory power supply backup system of claim 1, wherein the power supply switch unit switches to the power supply to deliver electric power when the power supply is back to normal.

6. The memory power supply backup system of claim 5, wherein the power supply backup unit further performs charge operation.

7. The memory power supply backup system of claim 1, wherein the power supply backup unit further includes a battery.

8. The memory power supply backup system of claim 1, wherein the power supply backup unit activates the backup power supply through the control signal.

9. The memory power supply backup system of claim 1, wherein the power supply backup unit closes the backup power supply through the control signal.

10. A power supply backup system for a computer system, comprising:
a memory to temporarily store data to be processed in the computer system;
a central processing unit to process the data;
a chip set to control signal transmission of the computer system;
a power delivery unit to receive power supply and provide electric power required in processes of the computer system;
a power detection unit to detect conditions of the power supply;
a power supply backup control unit to generate a control signal of a backup power supply according to the conditions of the power supply;
a power supply switch unit to switch a delivery route of the power supply according to the control signal; and
a power supply backup unit to provide the backup power supply to allow the memory to temporarily store the data.

11. The power supply backup system of claim 10, wherein the chip set includes a south bridge chip set and a north bridge chip set.

12. The power supply backup system of claim 10, wherein the power supply detection unit generates a power supply interruption signal when the power supply is interrupted.

13. The memory power supply backup system of claim 12, wherein the power supply interruption signal is a non-maskable interrupt instruction.

14. The memory power supply backup system of claim 10, wherein the power supply switch unit switches to the power supply backup unit to deliver electric power when the power supply is interrupted.

15. The memory power supply backup system of claim 10, wherein the power supply switch unit switches to the power supply to deliver electric power when the power supply is back to normal.

16. The memory power supply backup system of claim 15, wherein the power supply backup unit further performs charge operation.

17. The memory power supply backup system of claim 11, wherein the power supply backup unit further includes a battery.

18. The memory power supply backup system of claim 11, wherein the power supply backup unit activates the backup power supply through the control signal.

19. The memory power supply backup system of claim 11, wherein the power supply backup unit closes the backup power supply through the control signal.
